(19) United States
(12) Patent Application Publication
(10) Pub. No.: US 2005/0212103 A1
(43) Pub. Date: Sep. 29, 2005

(54) Semiconductor device designed to produce no resonance of loop due to ultrasonic vibration, semiconductor design apparatus and method of manufacturing semiconductor device

(75) Inventor: Yasuki Takata, Hyogo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/079,333

(22) Filed: Mar. 15, 2005

(30) Foreign Application Priority Data
Mar. 25, 2004 (JP) 2004-089945(P.)

(51) Int. Cl. H01L 21/48; H01L 23/52

(52) U.S. Cl. 257/673; 438/123; 257/784; 438/617

(57) ABSTRACT

A semiconductor device includes a semiconductor chip, an inner lead and a wire interconnecting a pad of the semiconductor chip with the inner lead. The wire is formed such that the eigenfrequency of the loop is outside a predetermined range of an ultrasonic vibration frequency used to form the loop. Accordingly, a rupture or break of a wire due to the resonance of a loop can be prevented.

### BACKGROUND OF THE INVENTION

1. Field of the Invention

The present invention relates to a technique of bonding a wire with a semiconductor chip and an inner lead to form a loop, and particularly to a semiconductor device designed to produce no resonance of a loop due to ultrasonic vibration during the formation of the loop using ultrasonic vibration as well as a semiconductor design apparatus for designing such a semiconductor device, and a method of manufacturing a semiconductor device.

2. Description of the Background Art

Presently, semiconductor devices are widely used in information communication devices such as computers and mobile phones, or household electrical appliances or the like. In general, such a semiconductor device is manufactured by interconnecting an inner lead and a pad of a semiconductor chip by a wire made of a metal such as Au to form a loop, where the connection of the wire is performed by ultrasonic and thermo compression wire bonding. Related techniques include the inventions disclosed in Japanese Patent Laying-Open Nos. 9-134932 and 2002-319596.

A wire bonding apparatus as disclosed in Japanese Patent Laying-Open No. 9-134932 includes a resonance frequency calculation unit calculating a resonance frequency of a wire loop formed by a wire between bonding points, an ultrasonic vibration frequency storage unit storing an ultrasonic vibration frequency of an ultrasonic vibration applied to a capillary, a comparison/determination unit comparing the resonance frequency with the ultrasonic vibration frequency to determine whether they coincide with each other or not, and a control unit driving the capillary in a controlled manner to perform wire bonding if the comparison/determination unit has determined that the resonance frequency does not coincide with the ultrasonic vibration frequency.

A connection method using wire bonding as disclosed in Japanese Patent Laying-Open No. 2002-319596 involves performing a first bonding and, with the wire being supported by a jig between a first bonding station and a second bonding station, performing a second bonding, thereby inhibiting resonance vibration of the wire from the second bonding and inhibiting the transmission of the vibration to the first bonding station.

A loop is composed of a wire of a finite length and connections at its both ends. A loop is generally formed by ultrasonic vibration. A loop is formed by first connecting a first end by ultrasonic vibration and subsequently connecting a second end by ultrasonic vibration.

Resonance of a loop occurs when the eigenfrequency of the portion of the wire between its first and second ends coincides, or approximately coincides, with the frequency of an ultrasonic vibration applied during the connection of the second end. It causes metal fatigue, which leads to a rupture or break of the wire. Conventionally, a semiconductor device was manufactured without taking the resonance of a loop into consideration.

The above-mentioned Japanese Patent Laying-Open No. 9-134932 discloses a controller driving a capillary in a controlled manner that takes the resonance of a loop into account, which, however, displaces a bonding point of the capillary to prevent the resonance and does not take other factors into consideration.

The above-mentioned Japanese Patent Laying-Open No. 2002-319596 prevents the resonance by a jig supporting the wire, which requires a mechanism for moving a jig which results in a semiconductor manufacturing apparatus with complicated structure.

### SUMMARY OF THE INVENTION

An object of the present invention is to provide a semiconductor device designed to prevent a rupture or break of a wire due to the resonance of a loop.

Another object of the present invention is to provide a semiconductor design apparatus that designs a semiconductor device so as to prevent a rupture or break of a wire due to the resonance of a loop.

Still another object of the present invention is to provide a method of manufacturing a semiconductor device that allows a wire to be connected without using ultrasonic vibration.

According to an aspect of the present invention, a semiconductor device includes: a semiconductor chip; an inner lead; and a wire interconnecting a pad of the semiconductor chip with the inner lead, where the wire is formed such that an eigenfrequency of a loop is outside a predetermined range of an ultrasonic vibration frequency used to form the loop.

Thus, a semiconductor device can be provided in which a rupture or break of a wire due to the resonance of a loop can be prevented.

According to another aspect of the present invention, a semiconductor design apparatus includes: a calculation unit calculating a loop length of a wire from plane coordinates of a pad of a semiconductor chip and an inner lead; a first determination unit determining a loop shape from the loop length of the wire calculated by the calculation unit; a second determination unit determining an eigenfrequency of the loop from the loop shape determined by the first determination unit; and a modification unit modifying the loop shape of the wire if the eigenfrequency of the loop determined by the second determination unit is within a predetermined range of an ultrasonic vibration frequency used to form the loop.

Thus, a semiconductor design apparatus can be provided that is capable of designing a semiconductor device in which a rupture or break of a wire due to the resonance of a loop can be prevented.

According to still another aspect of the present invention, a method of manufacturing a semiconductor device by interconnecting a pad of a semiconductor chip with an inner lead using a wire includes the steps of: heating work; pressing the wire against the inner lead; and moving the wire relative to the inner lead.

Thus, a wire can be connected without using ultrasonic vibration.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a relationship between the length and the eigenfrequency of a loop in a semiconductor device in a first embodiment of the present invention.

FIG. 2 is a Wiring Diagram (WD) schematically showing a semiconductor device in the first embodiment.

FIG. 3 shows a relationship between the height and the eigenfrequency of a loop in a semiconductor device in a second embodiment of the present invention.

FIG. 4 shows a relationship between the length and the eigenfrequency of a loop in a semiconductor device in a third embodiment of the present invention.

FIG. 5 shows a relationship between the diameter of a wire and the eigenfrequency of a loop in a semiconductor device in a fourth embodiment of the present invention.

FIG. 6 shows a relationship between the elastic modulus of a wire and the eigenfrequency of a loop in a semiconductor device in a fifth embodiment of the present invention.

FIG. 7 is a block diagram illustrating a configuration of a semiconductor design apparatus in a sixth embodiment of the present invention.

FIG. 8 is a block diagram showing a functional structure of the semiconductor design apparatus in the sixth embodiment of the present invention.

FIG. 9 is a flow chart illustrating a procedure for the semiconductor design apparatus in the sixth embodiment of the present invention.

FIG. 10 is a flow chart illustrating a procedure for a semiconductor design apparatus in a seventh embodiment of the present invention.

FIG. 11 illustrates a method of manufacturing a semiconductor device in an eighth embodiment of the present invention.

### DESCRIPTION OF THE PREFERRED EMBODIMENTS

### First Embodiment

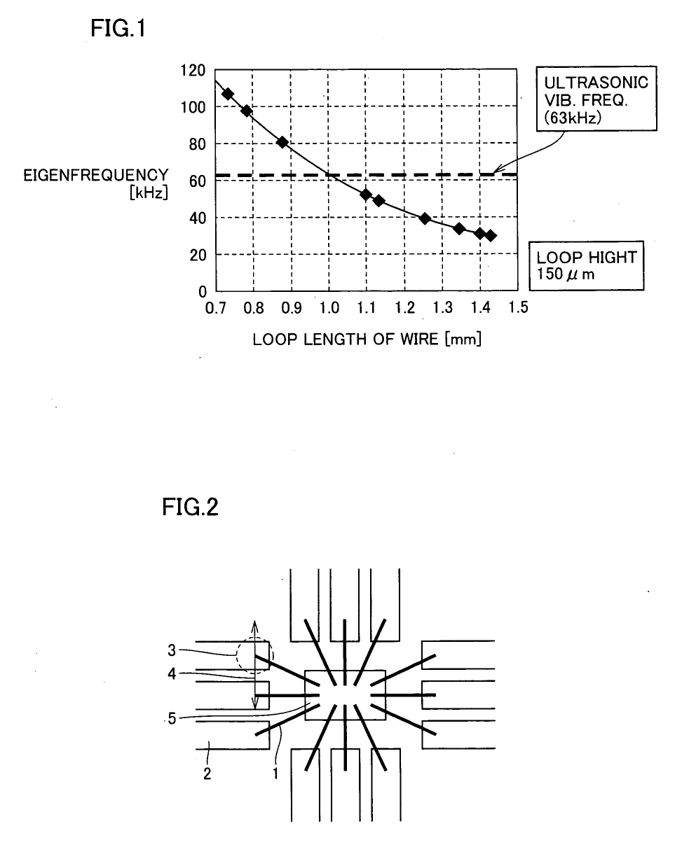

FIG. 1 shows a relationship between the length and the eigenfrequency of a loop in a semiconductor device in a first embodiment of the present invention. FIG. 1 shows eigenfrequencies (kHz) where the loop height of a wire is fixed at 150 μm and the loop length of a wire varies from 0.7 to 1.5 mm. The eigenfrequency can be obtained by a numerical calculation by the finite element method, for example, or by an experiment. It can be seen that an ultrasonic vibration frequency of a capillary of 63 kHz coincides with the eigenfrequency of a wire having a loop length of 1 mm. Accordingly, a capillary with an ultrasonic vibration frequency of 63 kHz causes resonance of a loop at or at around a loop length of 1 mm.

FIG. 2 is a WD schematically showing a semiconductor device in the first embodiment. The semiconductor device includes a plurality of inner leads 2, a semiconductor chip 5, and a plurality of loops 1 interconnecting inner leads 2 and pads of chip 5. A capillary 3 ultrasonically vibrates in the direction indicated by arrow 4 to connect wires 1 to inner leads 2.

In the present embodiment, the graph shown in FIG. 1 is used to find a loop length at which the ultrasonic vibration frequency of the capillary coincides, or approximately coincides, with the eigenfrequency and, accordingly, a WD as shown in FIG. 2 is laid out avoiding that length. A semiconductor device is then manufactured based on the created WD. The WD may also be created by finding a loop length at which the ultrasonic vibration frequency of a capillary coincides with the eigenfrequency and deciding a loop length outside a predetermined range relative to that loop length.

As described above, in a semiconductor device in the present embodiment, a loop height is fixed and a loop length is decided such that the ultrasonic vibration frequency of a capillary does not coincide or approximately coincide with the eigenfrequency, thereby preventing a rupture or break of a wire due to metal fatigue caused by the resonance of a loop.

### Second Embodiment

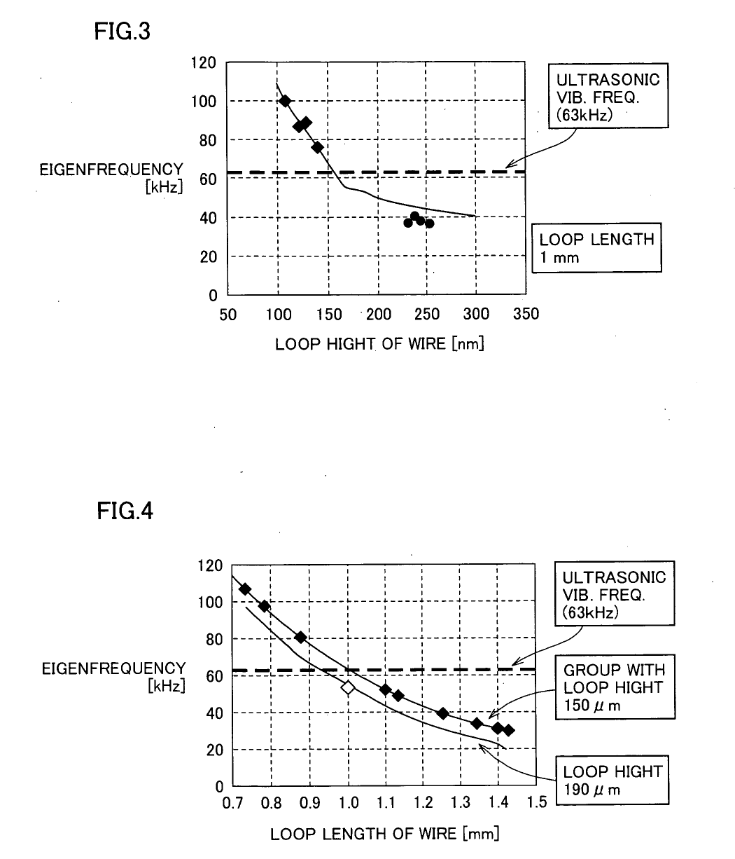

FIG. 3 shows a relationship between the height and the eigenfrequency of a loop in a semiconductor device in a second embodiment of the present invention. FIG. 3 shows eigenfrequencies (kHz) where the loop length of a wire is fixed at 1 mm and the loop height of a wire varies from 100 to 300 μm. The eigenfrequency may be obtained by a numerical calculation by the finite element method, for example, or by an experiment. It can be seen that an ultrasonic vibration frequency of a capillary of 63 kHz coincides with the eigenfrequency of a wire having a loop height of 150 μm. Accordingly, a capillary with an ultrasonic vibration frequency of 63 kHz causes resonance of a loop at or at around a loop height of 150 μm.

In the present embodiment, the graph shown in FIG. 3 is used to find a loop height at which the ultrasonic vibration frequency of a capillary coincides, or approximately coincides, with the eigenfrequency, and deciding a loop height uniformly for all the loops avoiding that height and laying out a WD as shown in FIG. 2. A semiconductor device is then manufactured based on the created WD. A WD may also be created by finding a loop height at which the ultrasonic vibration frequency of a capillary coincides with the eigenfrequency and deciding a loop height outside a predetermined range relative to that loop height.

As described above, in a semiconductor device in the present embodiment, a loop length is fixed and a loop height is decided such that the ultrasonic vibration frequency of a capillary does not coincide or approximately coincide with the eigenfrequency, thereby preventing a rupture or break of a wire due to metal fatigue caused by the resonance of a loop.

### Third Embodiment

FIG. 4 shows a relationship between the length and the eigenfrequency of a loop in a semiconductor device in a third embodiment of the present invention. FIG. 4 shows eigenfrequencies (kHz) where the loop height of a wire is fixed at 150 μm or 190 μm and the loop length of the wire varies from 0.7 to 1.5 mm. The eigenfrequency may be obtained by a numerical calculation by the finite element method, for example, or by an experiment. It can be seen that an ultrasonic vibration frequency of a capillary of 63 kHz coincides with the eigenfrequency of a wire having a loop length of 1 mm and a loop height of 150 μm.

In a case where the use of a wire with a loop length of 1 mm cannot be avoided, a WD as shown in FIG. 2 is laid out by changing the loop height from 150 μm to 190 μm, for example. A semiconductor device is then manufactured based on the created WD.

As described above, in a semiconductor device in the present embodiment, in a case where it cannot be avoided that the loop length is such that the ultrasonic vibration frequency of a capillary coincides, or approximately coincides, with the eigenfrequency, a loop height is decided such that the ultrasonic vibration frequency of the capillary does not coincide or approximately coincide with the eigenfrequency, thereby preventing a rupture or break of a wire due to metal fatigue caused by the resonance of a loop.

### Fourth Embodiment

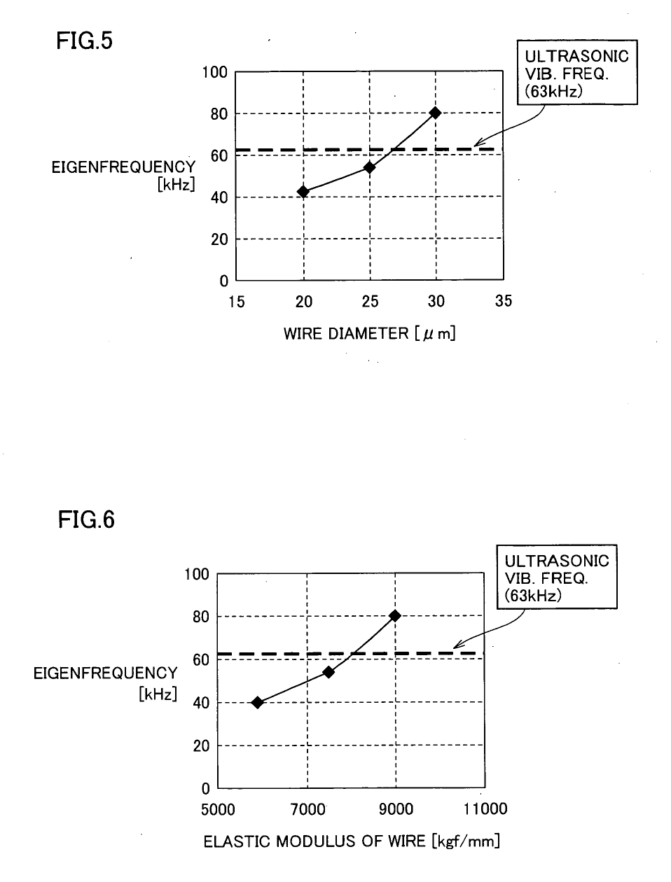

FIG. 5 shows a relationship between the diameter of a wire and the eigenfrequency of a loop in a semiconductor device in a fourth embodiment of the present invention. FIG. 5 shows eigenfrequencies (kHz) where the loop length of a wire is fixed at 1 mm and the loop height at 150 μm, and the diameter of the wire varies from 20 to 30 μm. The eigenfrequency may be obtained by a numerical calculation by the finite element method, for example, or by an experiment. It can be seen that an ultrasonic vibration frequency of a capillary of 63 kHz coincides with the eigenfrequency of a wire having a diameter of 27 μm.

In a case where the use of a wire with a loop length of 1 mm and a loop height of 150 μm cannot be avoided, the graph shown in FIG. 5 is used to find a wire diameter at which the ultrasonic vibration frequency of a capillary does not coincide or approximately coincide with the eigenfrequency, and a semiconductor device is manufactured using a wire with that diameter. It is also possible to find a wire diameter at which the ultrasonic vibration frequency of a capillary coincides with the eigenfrequency and decide a wire diameter outside a predetermined range relative to that wire diameter.

As described above, in a semiconductor device in the present embodiment, in a case where it cannot be avoided that the loop length and the loop height are such that the ultrasonic vibration frequency of a capillary coincides or approximately coincides with the eigenfrequency, a wire diameter is decided such that the ultrasonic vibration frequency of a capillary does not coincide or approximately coincide with the eigenfrequency, thereby preventing a rupture or break of a wire due to metal fatigue caused by the resonance of a loop.

### Fifth Embodiment

FIG. 6 shows a relationship between the elastic modulus of a wire and the eigenfrequency of a loop in a semiconductor device in a fifth embodiment of the present invention. FIG. 6 shows eigenfrequencies (kHz) where the loop length of a wire is fixed at 1 mm and the loop height at 150 μm, and the elastic modulus of the wire varies from 6,000 to 9,000 kgf/mm. The eigenfrequency may be obtained by a numerical calculation by the finite element method, for example, or by an experiment. It can be seen that an ultrasonic vibration frequency of a capillary of 63 kHz coincides with the eigenfrequency of a wire having an elastic modulus of 8,000 kgf/mm.

In a case where the use of a wire with a loop length of 1 mm and a loop height of 150 μm cannot be avoided, the graph shown in FIG. 6 is used to find an elastic modulus of a wire at which the ultrasonic vibration frequency of a capillary does not coincide or approximately coincide with the eigenfrequency, and a semiconductor device is manufactured using a wire with that elastic modulus. It is also possible to find an elastic modulus of a wire at which the ultrasonic vibration frequency of a capillary coincides with the eigenfrequency and decide an elastic modulus of a wire outside a predetermined range relative to that elastic modulus of the wire.

As described above, in a semiconductor device in the present embodiment, in a case where it cannot be avoided that the loop length and loop height are such that the ultrasonic vibration frequency of-a capillary coincides or approximately coincides with the eigenfrequency, an elastic modulus of a wire is decided such that the ultrasonic vibration frequency of a capillary does not coincide or approximately coincide with the eigenfrequency, thereby preventing a rupture or break of a wire due to metal fatigue caused by the resonance of a loop.

### Sixth Embodiment

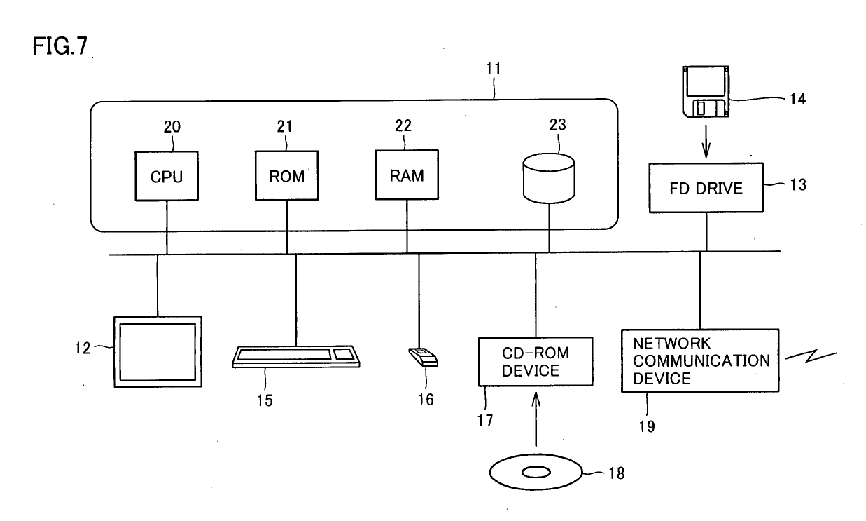

FIG. 7 is a block diagram illustrating a configuration of a semiconductor design apparatus in a sixth embodiment of the present invention. The semiconductor design apparatus includes a computer body 11, a display device 12, a Flexible Disk (FD) drive 13 that can be loaded with an FD 14, a keyboard 15, a mouse 16, a Compact Disc-Read Only Memory (CD-ROM) device 17 that can be loaded with a CD-ROM 18, and a network communication device 19.

A semiconductor design program is supplied via a storage medium such as an FD 14 or CD-ROM 18. Execution of the semiconductor design program by computer body 11 causes the designing of a semiconductor device. Alternatively, a semiconductor design program may be supplied from another computer to computer body 11 via network communication device 19.

Computer body 11 shown in FIG. 7 includes a Central Processing Unit (CPU) 20, Read Only Memory (ROM) 21, Random Access Memory (RAM) 22 and a hard disk 23. CPU 20 performs the processing as it exchanges data with display device 12, FD drive 13, keyboard 15, mouse 16, CD ROM device 17, network communication device 19, ROM 21, RAM 22, or hard disk 23.

The semiconductor design program on FD 14 or CD ROM 18 is directed by CPU 20 through FD drive 13 or CD ROM device 17 to be stored on hard disk 23. CPU 20 loads the semiconductor design program into RAM 22 as needed from hard disk 23 and executes the program to cause the designing of a semiconductor device.

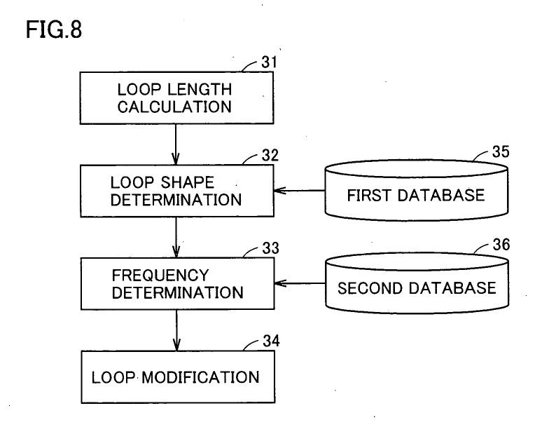

FIG. 8 is a block diagram showing a functional structure of the semiconductor design apparatus in the sixth embodiment of the present invention. The semiconductor design apparatus includes: a loop length calculation unit 31 calculating the loop length of a wire from Computer Aided Design (CAD) plane coordinates; a loop shape determination unit 32 determining the loop shape from the loop length calculated by loop length calculation unit 31; a frequency determination unit 33 determining the eigenfrequency of the loop from the loop shape determined by loop shape determination unit 32; a loop modification unit 34 modifying the loop length based on the eigenfrequency of the loop determined by frequency determination unit 33; a first database 35 used by loop shape determination unit 32 to determine the loop shape; and a second database 36 used by frequency determination unit 33 to determine the eigenfrequency of the loop.

First database 35 holds as a database a relationship between a loop length and a loop shape of a wire. While the loop shape may be represented as a function of a loop length and a loop height of a wire, the present embodiment provides a constant loop height and determines a loop shape from the loop length of a wire.

Second database 36 holds as a database a relationship between a loop shape and an eigenfrequency of the loop of a wire as shown in FIGS. 1 and 3 to 6, for example. Thus, the eigenfrequency of a loop can be determined from the wire shape.

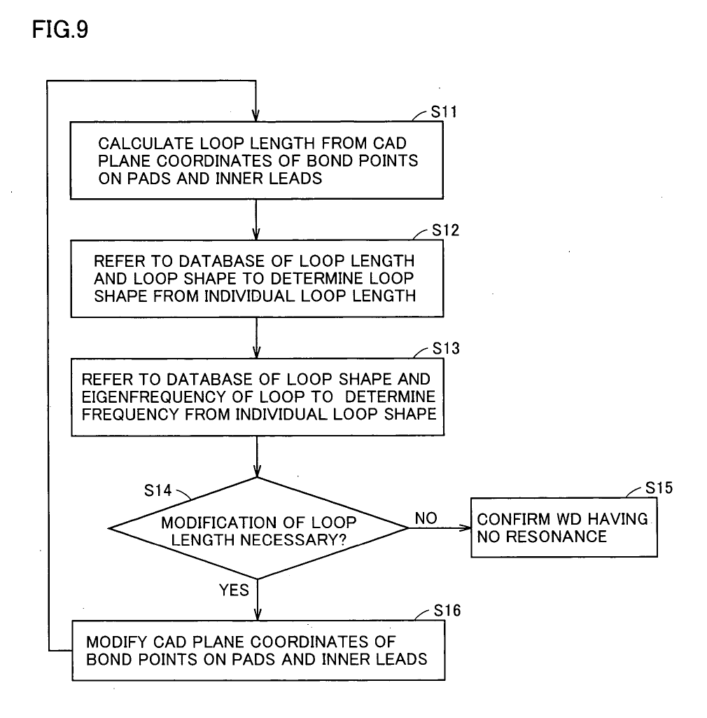

FIG. 9 is a flow chart illustrating a procedure for the semiconductor design apparatus in the sixth embodiment of the present invention. First, loop length calculation unit 31 calculates a loop length from CAD plane coordinates of bond points on pads of chip 5 and inner leads (S11).

Loop shape determination unit 32 then refers to first database 35 to extract a loop shape corresponding to the loop length calculated by loop length calculation unit 31, and thus determines the loop shape of each wire (S12).

Next, frequency determination unit 33 refers to second database 36 to extract an eigenfrequency of the loop from the loop shape of each wire determined by loop shape determination unit 32 and determines the eigenfrequency of each loop (S13). Determination is then made as to whether or not the loop length needs to be modified by comparing the eigenfrequency of each loop with the ultrasonic vibration frequency of a capillary (S14). The process may be performed depending on whether the absolute value of the difference between the eigenfrequency of a loop and the ultrasonic vibration frequency of a capillary is not more than a predetermined threshold.

If the loop length does not need to be modified (S14, No), the WD is confirmed without modifying the loop length of the wires (S15). If the loop length needs to be modified (S14, Yes), the CAD plane coordinates of the bond points on the pads of chip 5 and the inner leads are changed to modify the loop length of a wire (S16), and the procedure returns to step S11 and repeats the following processes.

As described above, in a semiconductor design apparatus in the present embodiment, the eigenfrequency of each loop determined by referring to a database is compared with the ultrasonic vibration frequency of a capillary, and CAD plane coordinates are changed if the loop length of a wire needs to be modified, thereby providing the designing of a semiconductor device such that a rupture or break of a wire due to metal fatigue caused by the resonance of a loop can be prevented.

### Seventh Embodiment

An exemplary structure of a semiconductor design apparatus according to a seventh embodiment of the present invention is similar to that of a semiconductor design apparatus according to the sixth embodiment as shown in FIG. 7. Further, the functional structure of the semiconductor design apparatus according to the seventh embodiment of the present invention only differs from that of the semiconductor design apparatus according to the sixth embodiment as shown in FIG. 8 in the functions of the first database and the loop modification unit. As such, detailed description of a like structure and function is not repeated. The following description refers to the first database and the loop modification unit in the present embodiment represented by the reference numbers 35′ and 34′, respectively.

First database 35′ holds as a database a relationship between a loop height and a loop shape of a wire. While the loop shape may be represented as a function of a loop length and a loop height of a wire, the present embodiment provides a constant loop length and determines a loop shape from the loop height of a wire. Loop modification unit 34′ modifies the loop height based on the eigenfrequency of the loop determined by frequency determination unit 33.

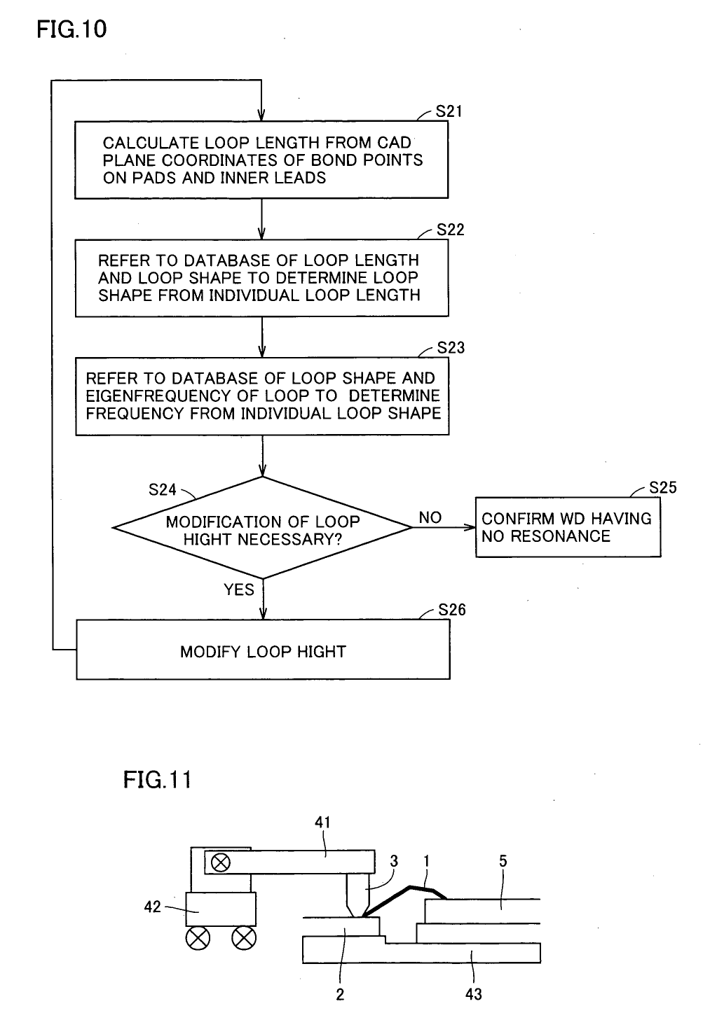

FIG. 10 is a flow chart illustrating a procedure for a semiconductor design apparatus in a seventh embodiment of the present invention. First, loop length calculation unit 31 calculates a loop length from CAD plane coordinates of bond points on pads of chip 5 and inner leads (S21).

Loop shape determination unit 32 then refers to first database 35′ to extract a loop shape corresponding to the loop length calculated by loop length calculation unit 31, and determines the loop shape of each wire (S22).

Next, frequency determination unit 33 refers to second database 36 to extract the eigenfrequency of the loop from the loop shape of each wire determined by loop shape determination unit 32, and determines the eigenfrequency of each loop (S23). Determination is then made as to whether the loop height needs to be modified by comparing the eigenfrequency of each loop with the ultrasonic vibration frequency of a capillary (S24). The process may be performed depending on whether the absolute value of the difference between the eigenfrequency of a loop and the ultrasonic vibration frequency of a capillary is not more than a predetermined threshold.

If the loop height does not need to be modified (S24, No), the WD is confirmed without modifying the loop height of the wires (S25). If the loop height needs to be modified (S24, Yes), the loop height of each wire is modified (S26) and the procedure returns to step S21 and repeats the following processes.

As described above, in a semiconductor design apparatus in the present embodiment, the eigenfrequency of each loop determined by referring to a database is compared with the ultrasonic vibration frequency of a capillary to modify, depending on the results, the loop height of a wire, thereby providing the designing of a semiconductor device such that a rupture or break of a wire due to metal fatigue caused by the resonance of a loop can be prevented.

### Eighth Embodiment

FIG. 11 illustrates a method of manufacturing a semiconductor device in an eighth embodiment of the present invention. The present method of manufacturing a semiconductor device forms a loop without using ultrasonic vibration. A heater 43 heats work to connect a wire 1 to an inner lead 2. Wire 1 is then pressed downward by a capillary 3 provided on a bonding head 41, while wire 1 is moved relative to inner lead 2 using an XY table 42.

Thus, wire 1 is connected to inner lead 2 by means of thermal energy from heated work, the load from wire 1 pressed downward by capillary 3, and the friction force from XY table 42 being moved:

As described above, a method of manufacturing a semiconductor device in the present embodiment is capable of connecting wire 1 to inner lead 2 without using ultrasonic vibration, thereby preventing a rupture or break of a wire due to the resonance of a loop.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device comprising:
a semiconductor chip;
an inner lead; and
a wire interconnecting a pad of said semiconductor chip with said inner lead,
wherein said wire is formed such that an eigenfrequency of a loop is outside a predetermined range of an ultrasonic vibration frequency used to form the loop.

2. The semiconductor device according to claim 1, wherein said wire has such a loop length that the eigenfrequency of the loop is outside the predetermined range of the ultrasonic vibration frequency used to form the loop.

3. The semiconductor device according to claim 1, wherein said wire has such a loop height that the eigenfrequency of the loop is outside the predetermined range of the ultrasonic vibration frequency used to form the loop.

4. The semiconductor device according to claim 1, wherein said wire has a loop height corresponding to a loop length such that the eigenfrequency of the loop is outside the predetermined range of the ultrasonic vibration frequency used to form the loop.

5. The semiconductor device according to claim 1, wherein said wire has such a diameter that the eigenfrequency of the loop is outside the predetermined range of the ultrasonic vibration frequency used to form the loop.

6. The semiconductor device according to claim 1, wherein said wire has such an elastic modulus that the eigenfrequency of the loop is outside the predetermined range of the ultrasonic vibration frequency used to form the loop.

7. A semiconductor design apparatus comprising:
a calculation unit calculating a loop length of a wire from plane coordinates of a pad of a semiconductor chip and an inner lead;
a first determination unit determining a loop shape from the loop length of the wire calculated by said calculation unit;
a second determination unit determining an eigenfrequency of the loop from the loop shape determined by said first determination unit; and
a modification unit modifying the loop shape of the wire if the eigenfrequency of the loop determined by said second determination unit is within a predetermined range of an ultrasonic vibration frequency used to form the loop.

8. The semiconductor design apparatus according to claim 7, wherein said modification unit modifies the loop length of the wire if the eigenfrequency of the loop determined by said second determination unit is within the predetermined range of the ultrasonic vibration frequency used to form the loop.

9. The semiconductor design apparatus according to claim 7, wherein said modification unit modifies a loop height of the wire if the eigenfrequency of the loop determined by said second determination unit is within the predetermined range of the ultrasonic vibration frequency used to form the loop.

10. A method of manufacturing a semiconductor device by interconnecting a pad of a semiconductor chip with an inner lead using a wire, the method comprising the steps of:
heating work;
pressing said wire against said inner lead; and
moving said wire relative to the inner lead.
